(19) United States
(12) Patent Application Publication
(10) Pub. No.: US 2025/0216421 A1
(43) Pub. Date: Jul. 3, 2025

(54) SHUNT RESISTOR AND CURRENT DETECTION APPARATUS

(71) Applicant: KOA CORPORATION, Ina-shi, Nagano (JP)

(72) Inventor: Tamotsu Endo, Ina-shi, Nagano (JP)

(73) Assignee: KOA CORPORATION, Ina-shi, Nagano (JP)

(21) Appl. No.: 18/849,877

(22) PCT Filed: Mar. 17, 2023
(86) PCT No.: PCT/JP2023/010638

§ 371 Date: Sep. 23, 2024

(30) Foreign Application Priority Data
Mar. 28, 2022 (JP) 2022-051426

(51) Int. Cl. G01R 15/14; G01K 7/00

(52) U.S. Cl. CPC G01R 15/146; G01K 7/00

(57) ABSTRACT

The present invention relates to a shunt resistor and a current detection apparatus. A current detector (2) includes voltage detection terminals (8A, 8B) provided at first characteristic positions of the electrodes (6, 7) where a temperature coefficient of resistance of a shunt resistor (1) has a first coefficient, and voltage detection terminals (8C, 8D) provided at second characteristic positions of the electrodes (6, 7) where a temperature coefficient of resistance of the shunt resistor (1) has a second coefficient. The first coefficient and the second coefficient have different numerical values.

### TECHNICAL FIELD

The present invention relates to a shunt resistor and a current detection apparatus.

### BACKGROUND ART

A shunt resistor is widely used for current detection. In order to enable current detection with little effect of temperature fluctuation, a temperature coefficient of resistance (TCR) of the shunt resistor is required to be as close to 0 as possible. The temperature coefficient of resistance (TCR) is an index showing a rate of change in resistance value due to temperature change. As the temperature coefficient of resistance (TCR) approaches 0, the change in resistance value becomes small. In order to improve the TCR of the shunt resistor, an alloy with a small TCR, such as Manganin (registered trademark), may be used as a material of the resistor.

A current detection apparatus having the shunt resistor is used in various applications, such as inverter device, converter device, battery management system (BMS) for monitoring a battery in electric vehicle, and battery storage system (BSS) for energy storage in power grid. In particular, in applications for monitoring battery energy storage, initial measurement accuracy (shipping adjustment accuracy), measurement accuracy for temperature fluctuation, and measurement accuracy for aging are considered to be more important than in other applications. The current detection apparatus affects a battery capacity design required for the entire system and determines system cost. For this reason, the current detection apparatus is required to have high measurement accuracy over a wide range of currents.

### CITATION LIST

### Patent Literature

Patent document 1: Japanese laid-open patent publication No. 2003-518763

### SUMMARY OF INVENTION

### Technical Problem

The current detection board detects the current by measuring a voltage drop at a voltage measurement position of the shunt resistor. However, the resistance value of the shunt resistor changes depending on the temperature. In other words, even if the current flowing through the shunt resistor is constant, the detected voltage can change depending on the temperature. As a result, the accuracy of the current measurement may be lowered.

Therefore, the present invention provides a shunt resistor and a current detection apparatus that can accurately detect a current flowing through the shunt resistor even if a temperature of the shunt resistor changes.

### Solution to Problem

In an embodiment, there is provided a shunt resistor comprising: a resistance element; a first electrode and a second electrode coupled to both sides of the resistance element; a first voltage detection terminal and a second voltage detection terminal provided at first characteristic positions of the first electrode and the second electrode where a temperature coefficient of resistance of the shunt resistor is a first coefficient; and a third voltage detection terminal and a fourth voltage detection terminal provided at second characteristic positions of the first electrode and the second electrode where the temperature coefficient of resistance of the shunt resistor is a second coefficient, the first coefficient and the second coefficient having different numerical values.

In an embodiment, the first coefficient has a negative numerical value, and the second coefficient has a positive numerical value.

In an embodiment, either the first voltage detection terminal and the third voltage detection terminal provided on the first electrode, or the second voltage detection terminal and the fourth voltage detection terminal provided on the second electrode comprise a common voltage detection terminal.

In an embodiment, there is provided a current detection apparatus comprising: a shunt resistor having a resistance element, a first electrode, and a second electrode, the first electrode and the second electrode being coupled to both sides of the resistor; and a current detector electrically coupled to the shunt resistor, the current detector including: a first voltage detection contact and a second voltage detection contact electrically coupled to negative characteristic positions of the first electrode and the second electrode where a temperature coefficient of resistance of the shunt resistor has a negative value; a third voltage detection contact and a fourth voltage detection contact electrically coupled to positive characteristic positions of the first electrode and the second electrode where a temperature coefficient of resistance of the shunt resistor has a positive value; a first voltage signal wire, a second voltage signal wire, a third voltage signal wire, and a fourth voltage signal wire coupled to the first voltage detection contact, the second voltage detection contact, the third voltage detection contact, and the fourth voltage detection contact, respectively; a resistor coupled to at least one of the first voltage signal wire, the second voltage signal wire, the third voltage signal wire, and the fourth voltage signal wire; a first voltage signal merging wire configured to merge voltage signals from the first voltage signal wire and the third voltage signal wire; and a second voltage signal merging wire configured to merge voltage signals from the second voltage signal wire and the fourth voltage signal wire, wherein the resistor has a resistance value that brings a temperature coefficient of resistance of the shunt resistor, calculated from voltage signals from the first voltage signal merging wire and the second voltage signal merging wire, close to zero.

In an embodiment, there is provided a current detection apparatus comprising: a shunt resistor having a resistance element, a first electrode, and a second electrode, the first electrode and the second electrode being coupled to both sides of the resistor; and a current detector electrically coupled to the shunt resistor, the current detector including: a first voltage detection contact and a second voltage detection contact electrically coupled to negative characteristic positions of the first electrode and the second electrode where a temperature coefficient of resistance of the shunt resistor has a negative value; a third voltage detection contact and a fourth voltage detection contact electrically coupled to positive characteristic positions of the first electrode and the second electrode where a temperature coefficient of resistance of the shunt resistor has a positive value; and a current calculator into which voltage signals from the first voltage detection contact, the second voltage detection contact, the third voltage detection contact, and the fourth voltage detection contact are input, wherein the current detector is configured to: correct at least one of a negative-characteristic-side detected voltage between the first voltage detection contact and the second voltage detection contact and a positive-characteristic-side detected voltage between the third voltage detection contact and the fourth voltage detection contact by multiplying a correction coefficient by at least one of the negative-characteristic-side detected voltage and the positive-characteristic-side detected voltage which are calculated from the voltage signals; and determine a current flowing through the shunt resistor based on a composite detection voltage calculated from a known resistance value of the shunt resistor and the negative-characteristic-side detected voltage and the positive-characteristic-side detected voltage, at least one of which has been corrected, and the correction coefficient has a numerical value that brings a temperature coefficient of resistance of the shunt resistor, calculated from the composite detection voltage, close to zero.

In an embodiment, there is provided a current detection apparatus comprising: a shunt resistor having a resistance element, a first electrode, and a second electrode, the first electrode and the second electrode being coupled to both sides of the resistor; and a current detector electrically coupled to the shunt resistor, the current detector including: a first voltage detection contact and a second voltage detection contact electrically coupled to first characteristic positions of the first electrode and the second electrode where a temperature coefficient of resistance of the shunt resistor has a first value; a third voltage detection contact and a fourth voltage detection contact electrically coupled to second characteristic positions of the first electrode and the second electrode where a temperature coefficient of resistance of the shunt resistor has a second value; and a current calculator into which voltage signals from the first voltage detection contact, the second voltage detection contact, the third voltage detection contact, and the fourth voltage detection contact are input, wherein the current calculator is configured to derive a value of a current flowing through the shunt resistor from a first characteristic-side detected voltage between the first voltage detection contact and the second voltage detection contact and a second characteristic-side detected voltage between the third voltage detection contact and the fourth voltage detection contact, the first characteristic-side detected voltage and the second characteristic-side detected voltage being calculated from the voltage signals.

In an embodiment, the current calculator has a current calculation formula configured to calculate the value of the current flowing through the shunt resistor from the first characteristic-side detected voltage and the second characteristic-side detected voltage.

In an embodiment, the current calculator has a data table showing a relationship between the first and second characteristic-side detected voltages and a value of a current flowing through the shunt resistor.

In an embodiment, the current calculator has a function of deriving a temperature of the shunt resistor from the first characteristic-side detected voltage and the second characteristic-side detected voltage.

### Advantageous Effects of Invention

According to the present invention, by selecting the resistance value of the resistor, the temperature coefficient of resistance (TCR) of the shunt resistor can be close to zero, thereby reducing the effect of the temperature of the shunt resistor and allowing the current flowing through the shunt resistor to be accurately determined.

Furthermore, according to the present invention, by multiplying the detected voltage by the correction coefficient, the temperature coefficient of resistance (TCR) of the shunt resistor can be close to zero, thereby reducing the effect of the temperature of the shunt resistor and allowing the current flowing through the shunt resistor to be accurately determined.

Furthermore, according to the present invention, the current flowing through the shunt resistor can be accurately determined from the first characteristic-side detected voltage and the second characteristic-side detected voltage.

### BRIEF DESCRIPTION OF DRAWINGS

FIG. 1 is a plan view showing a schematic diagram of one embodiment of a shunt resistor;

FIG. 2 is a perspective view of the shunt resistor shown in FIG. 1;

FIG. 3 is a graph showing a relationship between voltage detection position and voltage when a temperature of the shunt resistor is 20° C.;

FIG. 4 is a graph showing a relationship between voltage detection position and voltage when the temperature of the shunt resistor is 150° C.;

FIG. 5 is a graph showing a relationship between temperature-dependent voltage change of the shunt resistor and voltage detection position;

FIG. 6 is a graph showing a rate of change in resistance value of the shunt resistor at voltage detection positions P1, P2, and P3 shown in FIG. 5;

FIG. 7 is a perspective view showing an embodiment of a current detection apparatus including the shunt resistor shown in FIG. 1 and a current detector arranged on the shunt resistor;

FIG. 8 is a plan view of the current detection apparatus shown in FIG. 7;

FIG. 9 is a plan view showing an embodiment of the current detector electrically coupled to the shunt resistor;

FIG. 10 is a plan view schematically showing another embodiment of the shunt resistor;

FIG. 11 is a plan view schematically showing yet another embodiment of the shunt resistor;

FIG. 12 is a graph showing an example of a temperature coefficient of resistance of a shunt resistor;

FIG. 13 is a graph for explaining a manner in which the temperature coefficient of resistance of the shunt resistor is adjusted by first and second resistors which are positive-side resistors;

FIG. 14 is a graph showing another example of a temperature coefficient of resistance of a shunt resistor;

FIG. 15 is a graph for explaining a manner in which the temperature coefficient of resistance of the shunt resistor is adjusted by third and fourth resistors which are negative-side resistors;

FIG. 16 is a plan view showing another embodiment of the current measuring apparatus;

FIG. 17 is a graph explaining a manner in which the temperature coefficient of resistance of the shunt resistor is corrected;

FIG. 18 is a graph showing a relationship between voltage between first and second voltage detection contacts and the temperature of the shunt resistor;

FIG. 19 is a graph showing a relationship between voltage between third and fourth voltage detection contacts and the temperature of the shunt resistor;

FIG. 20 is a plan view schematically showing another embodiment of the shunt resistor; and

FIG. 21 is a plan view schematically showing yet another embodiment of the shunt resistor.

### DESCRIPTION OF EMBODIMENTS

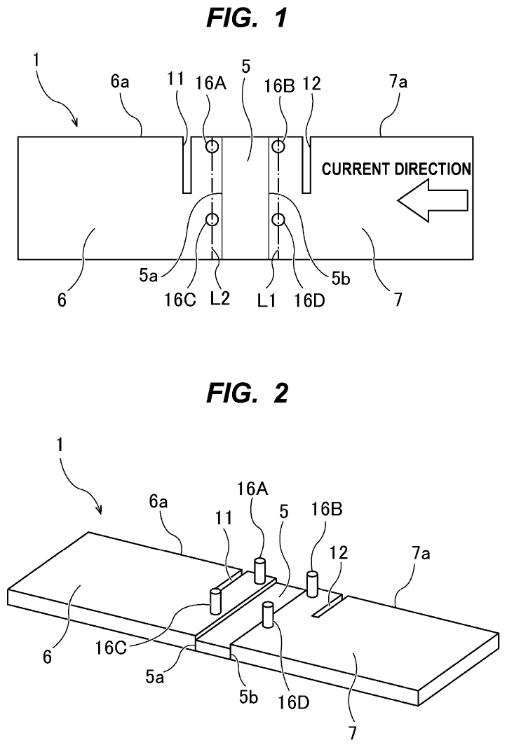

Hereinafter, embodiments of the present invention will be described with reference to the drawings. FIG. 1 is a plan view showing an embodiment of a shunt resistor, and FIG. 2 is a perspective view of the shunt resistor shown in FIG. 1. As shown in FIGS. 1 and 2, the shunt resistor 1 includes a resistance element 5 having a predetermined thickness and width, and a pair of first and second electrodes 6 and 7 made of a highly conductive metal coupled to both sides 5a and 5b of the resistance element 5. Specifically, the first electrode 6 is coupled to one side 5a of the resistance element 5, and the second electrode 7 is coupled to the other side 5b of the resistance element 5. The configuration of the second electrode 7 is the same as that of the first electrode 6. The first and second electrodes 6 and 7 are arranged symmetrically with respect to the resistance element 5. Hereinafter, the first and second electrodes 6 and 7 may be simply referred to as electrodes 6 and 7.

Examples of materials for the resistance element 5 include alloys, such as copper-nickel alloys, copper-manganese alloys, iron-chromium alloys, and nickel-chromium alloys. An example of a highly conductive metal for the electrodes 6, 7 is copper (Cu). Both ends 5a, 5b of the resistance element 5 are connected (joined) to the electrodes 6, 7 by means of welding (for example, electron beam welding, laser beam welding, or brazing and soldering) or other means.

In this embodiment, the thickness of the resistance element 5 is smaller than the thickness of the electrodes 6 and 7, and a front surface of the resistance element 5 is lower than front surfaces of the electrodes 6 and 7. However, in one embodiment, the thickness of the resistance element 5 may be the same as the thickness of the electrodes 6 and 7.

The electrodes 6 and 7 have slits 11 and 12, respectively. The slits 11 and 12 extend parallel to both ends 5a and 5b of the resistance element 5, respectively. In this embodiment, the slits 11 and 12 are cuts each extending in a straight line. The slit 11 extends in a straight line from a side surface 6a of the electrode 6 toward the center of the electrode 6, and the slit 12 extends in a straight line from a side surface 7a of the electrode 7 toward the center of the electrode 7. The slits 11 and 12 are located symmetrically with respect to the resistance element 5. In this embodiment, the slits 11 and 12 have the same width and the same length. The length of the slits 11 and 12 is a dimension of the slits 11 and 12 along both ends 5a and 5b of the resistance element 5.

The slits 11 and 12 formed in the electrodes 6 and 7 cause the current flowing through the shunt resistor 1 to avoid the slits 11 and 12. The current between the slits 11 and 12 flows around from an opposite-slit side, and a current density becomes lower toward the side surfaces 6a and 7a. A state of the current flowing through the shunt resistor 1 is different from a state of the current flowing through the shunt resistor 1 without a slit. In addition, a potential distribution of the shunt resistor 1 is different from a potential distribution of the shunt resistor 1 without a slit. As a result, a temperature coefficient of resistance (TCR) of the shunt resistor 1 changes significantly depending on a position at which a voltage between the slits 11 and 12 is detected, and is different from the temperature coefficient of resistance (TCR) of the shunt resistor 1 with no slits in the electrodes.

The shunt resistor 1 includes multiple pairs of voltage detection terminals 16A, 16B, 16C, and 16D fixed to the pair of electrodes 6 and 7. These voltage detection terminals 16A to 16D are pin terminals protruding from the electrodes 6 and 7. The voltage detection terminals 16A and 16C are fixed to the electrode 6, and the voltage detection terminals 16B and 16D are fixed to the electrode 7. The voltage detection terminals 16A to 16D are arranged along both sides 5a and 5b of the resistance element 5. In this embodiment, two pairs of voltage detection terminals are provided. The pair of voltage detection terminals 16A and 16B is arranged on the slit side, and the other pair of voltage detection terminals 16C and 16D is arranged on the opposite-slit side.

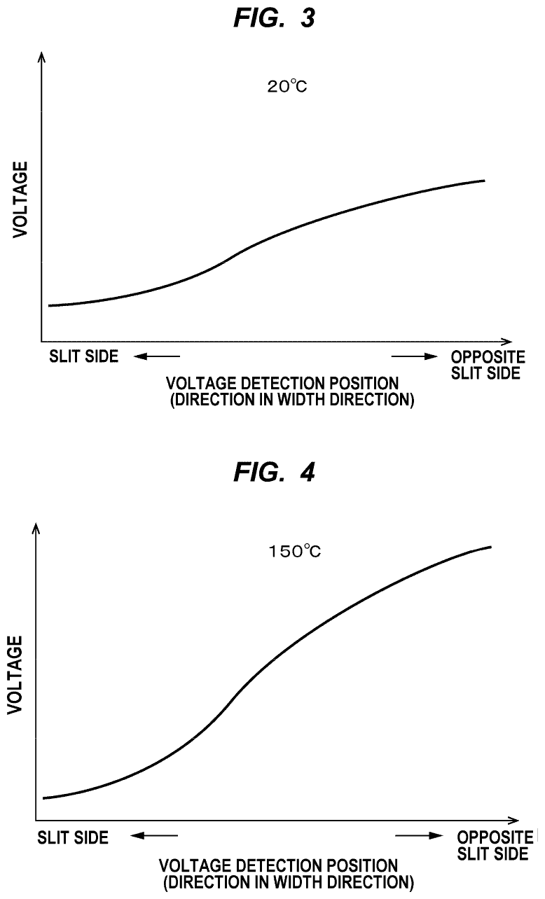

The temperature coefficient of resistance (TCR) of the shunt resistor 1 shown in FIG. 1 and FIG. 2 varies depending on the voltage detection position on the electrodes 6 and 7. FIG. 3 is a graph showing a relationship between voltage detection positions and voltage at the voltage detection positions when the temperature of the shunt resistor 1 is 20° C., and FIG. 4 is a graph showing a relationship between voltage detection positions and voltage when the temperature of the shunt resistor 1 is 150° C. The voltage detection positions are positions in the width direction of the shunt resistor 1 along both ends 5a and 5b of the resistance element 5. For example, the voltage detection positions are on dashed lines L1 and L2 in FIG. 1, and FIGS. 3 and 4 are graphs showing the relationship between the voltage detection positions on the dashed lines L1 and L2 and the voltage. In FIGS. 3 and 4, the current flowing through the shunt resistor 1 is constant in a direction from the electrode 7 to the electrode 6.

“Resistance value of the shunt resistor 1”, “rate of change in the resistance value of the shunt resistor 1”, and “temperature coefficient of resistance of the shunt resistor 1” are values calculated based on Ohm's law from the current flowing through the shunt resistor 1 and the detected voltage.

As can be seen from FIGS. 3 and 4, the detected voltage changes depending on the voltage detection positions (i.e., positions in the width direction). Specifically, the resistance value of the shunt resistor 1 changes depending on the voltage detection positions (i.e., positions in the width direction). In addition, a manner of the change in the detected voltage with the change in temperature differs between a position on the slit side and a position on the opposite-slit side. Specifically, as can be seen from the comparison between FIGS. 3 and 4, when the voltage detection positions are on the slit side, the detected voltage decreases as the temperature of the shunt resistor 1 rises from 20° C. to 150° C. On the other hand, when the voltage detection positions are on the opposite-slit side, the detected voltage increases as the temperature of the shunt resistor 1 rises from 20° C. to 150° C.

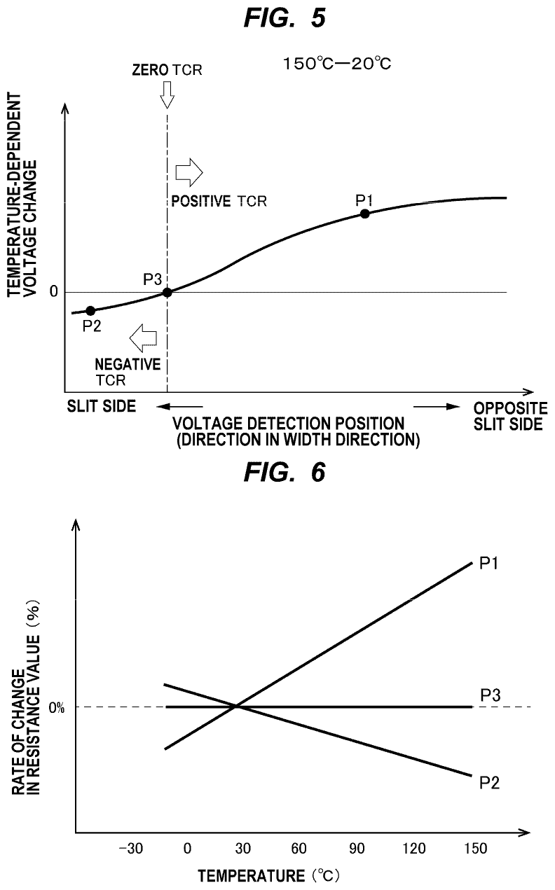

FIG. 5 is a graph showing a relationship between temperature-dependent voltage change of the shunt resistor 1 and the voltage detection positions. The temperature-dependent voltage change is a difference between a voltage at each voltage detection position when the temperature of the shunt resistor 1 is 150° C. and a voltage at the same voltage detection position when the temperature of the shunt resistor 1 is 20° C. As can be seen from the graph in FIG. 5, the detected voltage at the voltage detection position P1 on the opposite-slit side increases with the temperature rise of the shunt resistor 1 (i.e., the resistance value of the shunt resistor 1 increases). On the other hand, the detected voltage at the voltage detection position P2 on the slit side decreases with the temperature rise of the shunt resistor 1 (i.e., the resistance value of the shunt resistor 1 decreases). Furthermore, there is a voltage detection position P3 where the detected voltage does not change regardless of the temperature change of the shunt resistor 1 (i.e., the resistance value of the shunt resistor 1 does not change).

FIG. 6 is a graph showing the rate of change in the resistance value of the shunt resistor 1 calculated from the detected voltage at the voltage detection positions P1, P2, and P3 shown in FIG. 5. In FIG. 6, vertical axis represents the rate of change in the resistance value of the shunt resistor 1, and horizontal axis represents the temperature of the shunt resistor 1. A slope of the graph indicating the rate of change in the resistance value represents the temperature coefficient of resistance (TCR) of the shunt resistor 1. The temperature coefficient of resistance of the shunt resistor 1 calculated from the detected voltage at the voltage detection position P1 indicates that the resistance value of the shunt resistor 1 increases with the increase in temperature, and the temperature coefficient of resistance of the shunt resistor 1 calculated from the detected voltage at the voltage detection position P2 indicates that the resistance value of the shunt resistor 1 decreases with the increase in temperature. Furthermore, the temperature coefficient of resistance of the shunt resistor 1 calculated from the detected voltage at the voltage detection position P3 indicates that the resistance value of the shunt resistor 1 does not change with the increase in temperature.

In the following descriptions, a temperature coefficient of resistance indicating that the resistance value increases with the increase in temperature is referred to as a positive temperature coefficient of resistance, a temperature coefficient of resistance indicating that the resistance value decreases with the increase in temperature is referred to as a negative temperature coefficient of resistance, and a temperature coefficient of resistance indicating that the resistance value does not change with the increase in temperature is referred to as a zero temperature coefficient of resistance.

In the embodiments described below, two pairs of voltage detection terminals 16A to 16D are arranged at positions where a voltage is detected with the positive temperature coefficient of resistance of the shunt resistor 1 (hereinafter, these positions are referred to as positive characteristic positions) and at positions where a voltage is detected with the negative temperature coefficient of resistance of the shunt resistor 1 (hereinafter, these positions are referred to as negative characteristic positions), so that the detected voltage at the positive characteristic positions and the detected voltage at the negative characteristic positions are intentionally obtained. Then, the detected voltage at the positive characteristic positions and the detected voltage at the negative characteristic positions that are corrected, and the corrected detected voltage at the positive characteristic positions and the corrected detected voltage at the negative characteristic positions are then synthesized to approach the zero temperature coefficient of resistance.

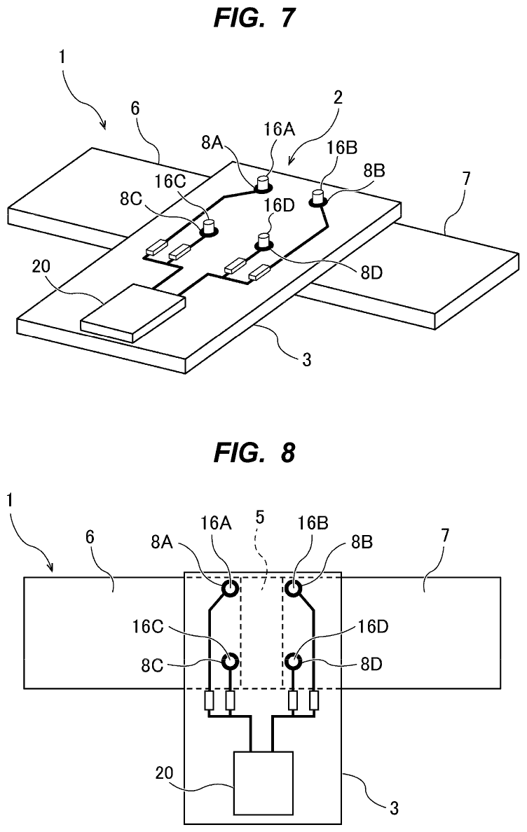

FIG. 7 is a perspective view showing one embodiment of a current detection apparatus including the shunt resistor 1 shown in FIG. 1 and a current detector 2 arranged on the shunt resistor 1, and FIG. 8 is a plan view of the current detection apparatus shown in FIG. 7. The current detection terminals 16A to 16D on the pair of electrodes 6, 7 are electrically coupled to the current detector 2. The current detector 2 has a base plate 3 on which a current calculator 20 and other structural elements are arranged. This base plate 3 is fixed to the current detection terminals 16A to 16D of the shunt resistor 1. An example of the base plate 3 is a printed circuit board made of a material, such as glass epoxy.

The current detector 2 includes a first voltage detection contact 8A and a second voltage detection contact 8B electrically coupled to the first current detection terminal 16A on the first electrode 6 and the second current detection terminal 16B on the second electrode 7, respectively. The current detector 2 further includes a third voltage detection contact 8C and a fourth voltage detection contact 8D electrically coupled to the third current detection terminal 16C on the first electrode 6 and the fourth current detection terminal 16D on the second electrode 7, respectively. In one embodiment, the current detection terminals 16A to 16D are inserted into holes formed in the base plate 3 and coupled to the voltage detection contacts by a method, such as soldering.

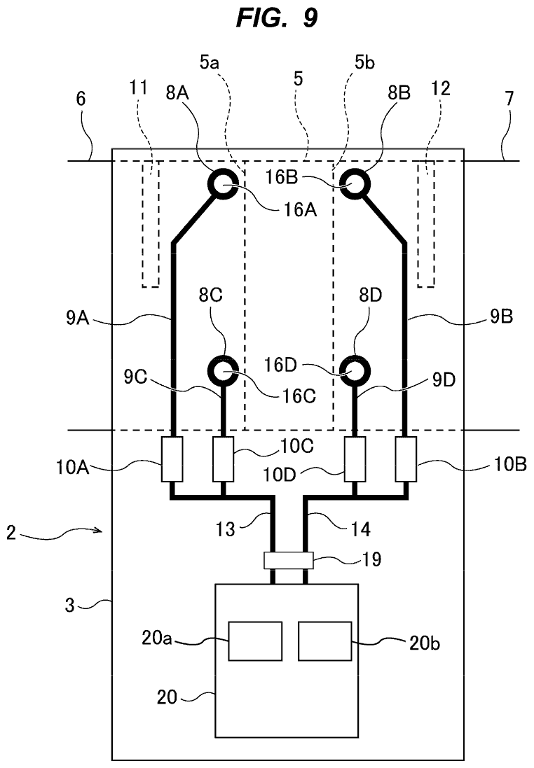

FIG. 9 is a plan view showing an embodiment of the current detector 2 electrically coupled to the shunt resistor 1. The first voltage detection contact 8A and the second voltage detection contact 8B are coupled via the current detection terminals 16A, 16B to the negative characteristic positions of the first electrode 6 and the second electrode 7 where a voltage is detected with a negative value of the temperature coefficient of resistance of the shunt resistor 1. At the negative characteristic positions, the detected voltage decreases with an increase in temperature, and the resistance value of the shunt resistor 1 calculated from the detected voltage decreases.

The first voltage detection contact 8A and the first current detection terminal 16A are adjacent to the slit 11 of the first electrode 6, and the second voltage detection contact 8B and the second current detection terminal 16B are adjacent to the slit 12 of the second electrode 7. More specifically, the first voltage detection contact 8A and the first current detection terminal 16A are located between the slit 11 of the first electrode 6 and the resistance element 5, and the second voltage detection contact 8B and the second current detection terminal 16B are located between the slit 12 of the second electrode 7 and the resistance element 5.

The third voltage detection contact 8C and the fourth voltage detection contact 8D are coupled via the current detection terminals 16C and 16D to the positive characteristic positions of the first electrode 6 and the second electrode 7 where a voltage is detected with a positive value of the temperature coefficient of resistance of the shunt resistor 1. At the positive characteristic positions, the detected voltage increases with an increase in temperature, and the resistance value of the shunt resistor 1 calculated from the detected voltage increases. The third voltage detection contact 8C, the fourth voltage detection contact 8D, the third current detection terminal 16C, and the fourth current detection terminal 16D are located away from the slits 11 and 12. More specifically, the third voltage detection contact 8C, the fourth voltage detection contact 8D, the third current detection terminal 16C, and the fourth current detection terminal 16D are located outside areas between the slits 11 and 12 and the resistance element 5.

The negative characteristic positions where the first voltage detection contact 8A and the second voltage detection contact 8B are coupled via the current detection terminals 16A, 16B, and the positive characteristic positions where the third voltage detection contact 8C and the fourth voltage detection contact 8D are coupled via the current detection terminals 16C, 16D can be determined based on results of a simulation or experiment that investigates the relationship between the voltage detection position and the temperature coefficient of resistance of the shunt resistor 1, as shown in FIGS. 3, 4 and 5.

In this embodiment, the first voltage detection contact 8A (the first voltage detection terminal 16A) and the second voltage detection contact 8B (the second voltage detection terminal 16B) form a pair that is symmetrically arranged with respect to the resistance element 5, and the third voltage detection contact 8C (the third voltage detection terminal 16C) and the fourth voltage detection contact 8D (the fourth voltage detection terminal 16D) also form a pair that is symmetrically arranged with respect to the resistance element 5. The first voltage detection contact 8A (the first voltage detection terminal 16A), the second voltage detection contact 8B (the second voltage detection terminal 16B), the third voltage detection contact 8C (the third voltage detection terminal 16C), and the fourth voltage detection contact 8D (the fourth voltage detection terminal 16D) are arranged along both sides 5a, 5b of the resistance element 5 and are adjacent to both sides 5a, 5b of the resistance element 5.

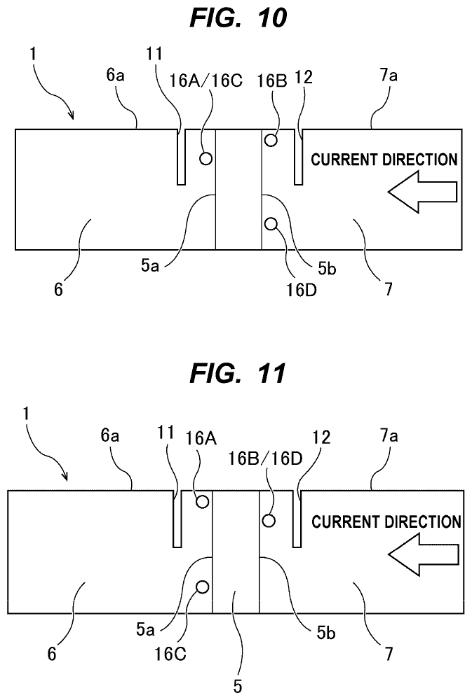

The voltage detection contacts 8A to 8D (the voltage detection terminals 16A to 16D) do not have to be arranged symmetrically with respect to the resistance element 5 as long as they are located at positions that provide a positive or negative temperature coefficient of resistance. In one embodiment, the voltage detection contacts 8A and 8C (the voltage detection terminals 16A and 16C) may be constituted of a common voltage detection contact (a common voltage detection terminal) as shown in FIG. 10, or the voltage detection contacts 8B and 8D (the voltage detection terminals 16B and 16D) may be constituted of a common voltage detection contact (a common voltage detection terminal) as shown in FIG. 11. For example, the voltage detection contacts (the voltage detection terminals) to be unified are arranged at positions where a potential does not vary with temperature. In this embodiment, the first voltage detection contact 8A, the second voltage detection contact 8B, the third voltage detection contact 8C, and the fourth voltage detection contact 8D are formed from through-holes that penetrate the base plate 3 from the back side to the front side of the base plate 3. The current detection terminals 16A to 16D are inserted through the first voltage detection contact 8A, the second voltage detection contact 8B, the third voltage detection contact 8C, and the fourth voltage detection contact 8D, which are electrically coupled to the current detection terminals 16A to 16D by a method, such as soldering. However, the form of electrical connection between the current detection position and the voltage detection contact of the shunt resistor 1 is not limited to the method of connecting by inserting the current detection terminal into the through-hole, and other method (for example, a method of surface-connecting the current detection position and the voltage detection contact of the shunt resistor 1 by soldering, etc.) may also be used.

The current detector 2 further includes a first voltage signal wire 9A, a second voltage signal wire 9B, a third voltage signal wire 9C, and a fourth voltage signal wire 9D coupled to the first voltage detection contact 8A, the second voltage detection contact 8B, the third voltage detection contact 8C, and the fourth voltage detection contact 8D, respectively. These voltage signal wires 9A to 9D are disposed on the front side of the base plate 3.

The current detector 2 further includes a first resistor 10A, a second resistor 10B, a third resistor 10C, and a fourth resistor 10D coupled to the first voltage signal wire 9A, the second voltage signal wire 9B, the third voltage signal wire 9C, and the fourth voltage signal wire 9D, respectively. These resistors 10A to 10D are also disposed on the front side of the base plate 3, as well as the voltage signal wires 9A to 9D.

The current detector 2 includes a first voltage signal merging wire 13 for merging voltage signals transmitted through the first resistor 10A and the third resistor 10C, and a second voltage signal merging wire 14 for merging voltage signals transmitted through the second resistor 10B and the fourth resistor 10D. The first voltage signal merging wire 13 is coupled to the first voltage signal wire 9A and the third voltage signal wire 9C, and the second voltage signal merging wire 14 is coupled to the second voltage signal wire 9B and the fourth voltage signal wire 9D. A capacitor 19 is provided between the first voltage signal merging wire 13 and the second voltage signal merging wire 14. The voltage signal merging wires 13 and 14 combine the voltage signal on an output side of the first resistor 10A and the voltage signal on an output side of the third resistor 10C, and combine the voltage signal on an output side of the second resistor 10B and the voltage signal on an output side of the fourth resistor 10D to form composite voltage signals, respectively.

The current detector 2 further includes a current calculator 20 coupled to the first voltage signal merging wire 13 and the second voltage signal merging wire 14. The current calculator 20 is configured to determine the current flowing through the shunt resistor 1 from a composite detection voltage calculated from the composite voltage signals and a known resistance value of the shunt resistor 1. In one embodiment, an amplifier for amplifying the voltage signals may be provided between the resistors 10A to 10D and the current calculator 20.

The current calculator 20 includes a memory 20a storing a program therein, and a arithmetic device 20b configured to perform arithmetic operations according to instructions included in the program. The current calculator 20 includes at least one small computer. The memory 20a includes a main memory, such as a random access memory (RAM), and an auxiliary memory, such as a hard disk drive (HDD) or a solid state drive (SSD). An example of the arithmetic device 20b is a central processing unit (CPU). However, the specific configuration of the current calculator 20 is not limited to these examples. In one embodiment, the current calculator 20 may be provided away from the base plate 3. Although not shown, the current detector 2 includes a connector coupled to an output signal wire of the current calculator 20, and an output signal may be output from the base plate 3 through the connector.

The composite detection voltage is calculated from the composite voltage signals from the voltage signal merging wires 13 and 14. The composite voltage signal from the voltage signal merging wire 13 can be adjusted by the resistance value(s) of the first resistor 10A and the third resistor 10C, and the composite voltage signal from the voltage signal merging wire 14 can be adjusted by the second resistor 10B and the fourth resistor 10D. In other words, the composite detection voltage calculated from the composite voltage signals from the voltage signal merging wires 13 and 14 can be adjusted by the resistance value(s) of the resistors 10A to 10D.

The first resistor 10A and the second resistor 10B are negative-side resistors electrically coupled to the first voltage detection contact 8A and the second voltage detection contact 8B, and the third resistor 10C and the fourth resistor 10D are positive-side resistors electrically coupled to the third voltage detection contact 8C and the fourth voltage detection contact 8D. The negative-side resistors (i.e., the first resistor 10A and the second resistor 10B) or the positive-side resistors (i.e., the third resistor 10C and the fourth resistor 10D) have a resistance value that makes the temperature coefficient of resistance of the shunt resistor 1 close to 0, wherein the temperature coefficient of resistance of the shunt resistor 1 is calculated from the voltage signals from the first voltage signal merging wire 13 and the second voltage signal merging wire 14.

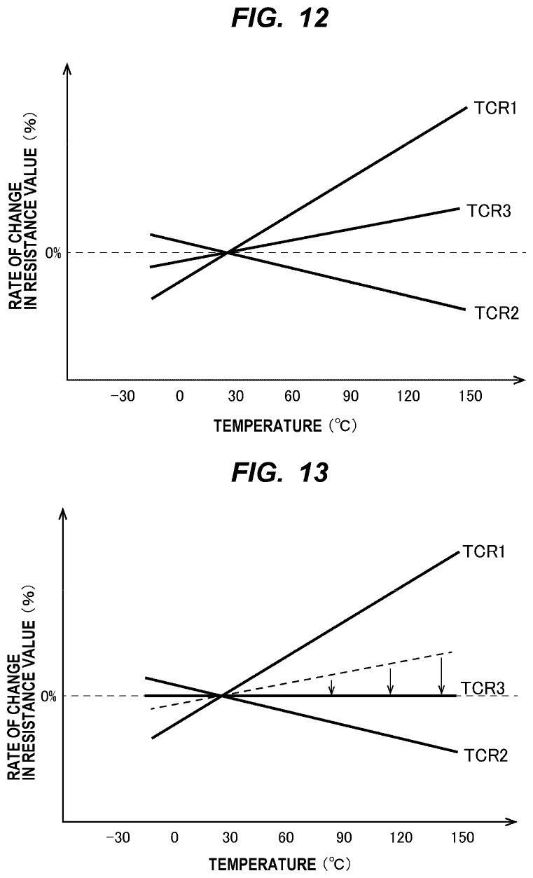

FIG. 12 is a graph showing an example of the temperature coefficient of resistance of the shunt resistor 1 with 25° C. as a reference temperature when the first resistor 10A, the second resistor 10B, the third resistor 10C, and the fourth resistor 10D have the same resistance value. A symbol TCR2 represents a temperature coefficient of resistance of the shunt resistor 1 calculated from a negative-characteristic-side detected voltage between the first voltage detection contact 8A and the second voltage detection contact 8B. More specifically, the symbol TCR2 represents the temperature coefficient of resistance of the shunt resistor 1 calculated from the voltage signals on the output sides of the first resistor 10A and the second resistor 10B, which are negative-side resistors. A symbol TCR1 represents a temperature coefficient of resistance of the shunt resistor 1 calculated from a positive-characteristic-side detected voltage between the third voltage detection contact 8C and the fourth voltage detection contact 8D. More specifically, the symbol TCR1 represents the temperature coefficient of resistance of the shunt resistor 1 calculated from the voltage signals on the output sides of the third resistor 10C and the fourth resistor 10D, which are positive-side resistors.

A symbol TCR3 represents a temperature coefficient of resistance of the shunt resistor 1 calculated from the composite detection voltage, and more specifically, represents the temperature coefficient of resistance of the shunt resistor 1 calculated from the composite voltage signals from the voltage signal merging wires 13, 14. The voltage signal on the output side of the first resistor 10A and the voltage signal on the output side of the third resistor 10C are merged by the voltage signal merging wire 13 to form the composite voltage signal, while the voltage signal on the output side of the second resistor 10B and the voltage signal on the output side of the fourth resistor 10D are merged by the voltage signal merging wire 14 to form the composite voltage signal. When the first resistor 10A, the second resistor 10B, the third resistor 10C, and the fourth resistor 10D have the same resistance value, the voltage signal on the input side of the first resistor 10A and the voltage signal on the input side of the third resistor 10C are merged at a ratio of 1:1 to form the composite voltage signal, while the voltage signal on the input side of the second resistor 10B and the input signal on the input side of the fourth resistor 10D are merged at a ratio of 1:1 to form the composite voltage signal. The composite detection voltage is calculated from the composite voltage signals from the voltage signal merging wires 13 and 14.

As can be seen from FIG. 12, the temperature coefficient of resistance TCR1 calculated from the positive-characteristic-side detected voltage between the third voltage detection contact 8C and the fourth voltage detection contact 8D is a positive temperature coefficient of resistance in which the resistance value of the shunt resistor 1 increases with the increase in temperature. The temperature coefficient of resistance TCR2 calculated from the negative-characteristic-side detected voltage between the first voltage detection contact 8A and the second voltage detection contact 8B is a negative temperature coefficient of resistance in which the resistance value of the shunt resistor 1 decreases with the increase in temperature. The temperature coefficient of resistance TCR3 calculated from the composite detection voltage is a positive temperature coefficient of resistance in which the resistance value increases with the increase in temperature.

As shown in FIG. 13, the temperature coefficient of resistance TCR3 is brought close to 0 by changing the resistance value of at least one of the first resistor 10A, the second resistor 10B, the third resistor 10C, and the fourth resistor 10D electrically coupled to the voltage detection contacts 8A to 8D. In this embodiment, the first resistor 10A and the second resistor 10B, which are negative-side resistors, have the same resistance value, and the third resistor 10C and the fourth resistor 10D, which are positive-side resistors, have the same resistance value. The resistance value of either the negative-side resistors or the positive-side resistors, or the resistance values of both the negative-side resistors and the positive-side resistors are changed such that the resistance value of the negative-side resistors and the resistance value of the positive-side resistors are not the same so as to bring the temperature coefficient of resistance TCR3 close to 0.

The first resistor 10A, the second resistor 10B, the third resistor 10C, and the fourth resistor 10D may be resistors whose resistance value can be adjusted after the resistors 10A, 10B, 10C, and 10D are coupled. In this case, it is preferable to adjust the resistance value of at least one of the first resistor 10A, the second resistor 10B, the third resistor 10C, and the fourth resistor 10D until the temperature coefficient of resistance TCR3 becomes 0 (i.e., until the slope of the graph showing TCR3 becomes 0). However, due to the property of the material of the resistance element 5, the graph showing TCR3 may be curved. Therefore, the resistance values of the first resistor 10A, the second resistor 10B, the third resistor 10C, and the fourth resistor 10D are selected such that the temperature coefficient of resistance TCR3 falls within an allowable range. The allowable range is a range including 0 and is set in advance.

By selecting the resistance values of the first resistor 10A, the second resistor 10B, the third resistor 10C, and the fourth resistor 10D in this manner, the temperature coefficient of resistance TCR3 of the shunt resistor 1 approaches 0 (preferably the temperature coefficient of resistance TCR3 becomes 0), so that the current calculator 20 can accurately determine the current without being affected by the temperature of the shunt resistor 1.

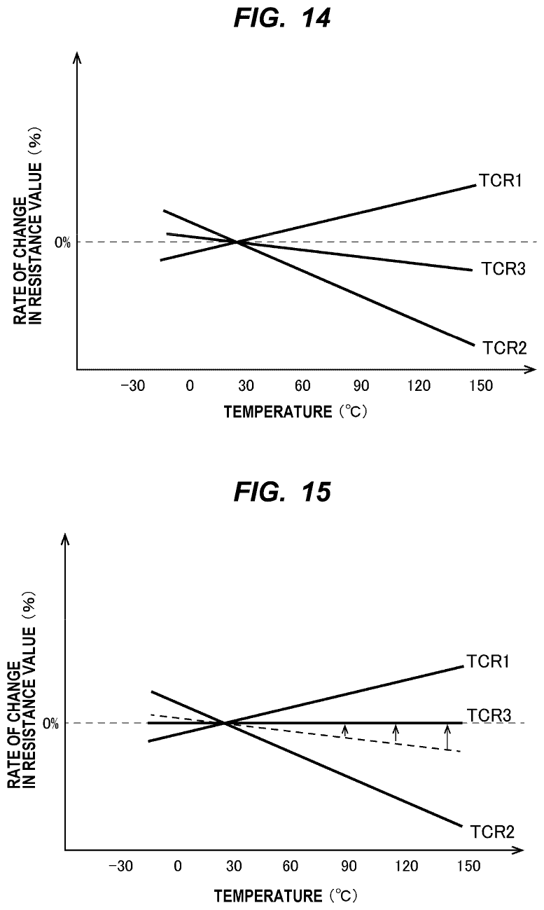

FIG. 14 is a graph showing another example of the temperature coefficient of resistance of the shunt resistor 1 with 25° C. as the reference temperature when the first resistor 10A, the second resistor 10B, the third resistor 10C, and the fourth resistor 10D all have the same resistance value. In this example, the temperature coefficient of resistance TCR3 of the shunt resistor 1 calculated from the composite detection voltage is a negative temperature coefficient of resistance.

In this case, as shown in FIG. 15, the resistance value of at least one of the first resistor 10A, the second resistor 10B, the third resistor 10C, and the fourth resistor 10D electrically coupled to the voltage detection contacts 8A to 8D is changed to bring the temperature coefficient of resistance TCR3 close to 0. In this embodiment, the first resistor 10A and the second resistor 10B, which are the negative-side resistors, have the same resistance value, and the first resistor 10C and the second resistor 10D, which are the positive-side resistors, have the same resistance value. The resistance value of either the negative-side resistors or the positive-side resistors, or the resistance values of both the negative-side resistors and the positive-side resistors are changed such that the resistance value of the negative-side resistors and the resistance value of the positive-side resistors are not the same so as to bring the temperature coefficient of resistance TCR3 close to 0.

The first resistor 10A, the second resistor 10B, the third resistor 10C, and the fourth resistor 10D may be resistors whose resistance value can be adjusted after the resistors 10A, 10B, 10C, and 10D are coupled. In this case, it is preferable to adjust the resistance value of at least one of the first resistor 10A, the second resistor 10B, the third resistor 10C, and the fourth resistor 10D until the temperature coefficient of resistance TCR3 becomes 0 (i.e., until the slope of the graph showing TCR3 becomes 0). However, due to the property of the material of the resistance element 5, the graph showing TCR3 may be curved. Therefore, the resistance values of the first resistor 10A, the second resistor 10B, the third resistor 10C, and the fourth resistor 10D are selected such that the temperature coefficient of resistance TCR3 falls within an allowable range. The allowable range is a range including 0 and is set in advance.

The resistance values of the resistors 10A to 10D are determined in advance by simulation or the like. In the case of using resistors whose resistance values can be adjusted, the resistance values can be further adjusted after the current detection apparatus is manufactured (before shipment). Specifically, while a predetermined current is passed through the shunt resistor 1, the composite detection voltage is measured by the current calculator 20 while changing the temperature of the shunt resistor 1, and the resistance value(s) of the first resistor 10A and the second resistor 10B and/or the resistance value(s) of the third resistor 10C and the fourth resistor 10D are adjusted in a direction in which the change in the composite detection voltage becomes smaller (i.e., in a direction in which the temperature coefficient of resistance TCR3 approaches 0). By adjusting the resistance value(s) in this way, the temperature coefficient of resistance of the shunt resistor 1 approaches 0, so that the current detection apparatus is able to accurately measure the current without being affected by the temperature of the shunt resistor 1.

In one embodiment, the negative characteristic position and the positive characteristic position may be positions where an influence of skin effect due to frequency is small. The negative characteristic position is a position where the negative temperature coefficient of resistance is established and where the influence of the skin effect due to frequency is small, and the positive characteristic position is a position where the positive temperature coefficient of resistance is established and where the influence of the skin effect due to frequency is small. This makes it possible to accurately measure the current without being influenced by the temperature of the shunt resistor 1 and without being influenced by the skin effect due to frequency.

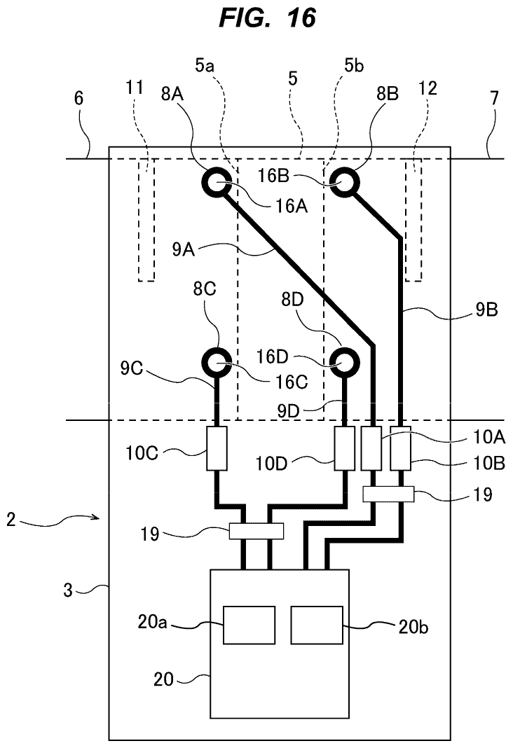

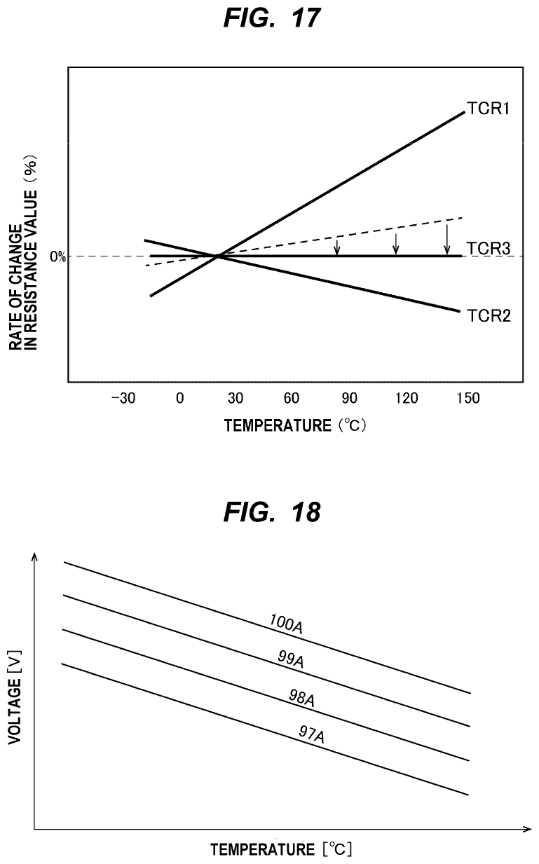

Next, another embodiment of the current measuring apparatus will be described with reference to FIGS. 16 and 17. Configuration and operation of this embodiment that are not specifically described are the same as those of the embodiments described with reference to FIGS. 1 to 15, and duplicated descriptions will be omitted. FIG. 16 is a plan view showing another embodiment of the current measuring apparatus.

The first resistor 10A, the second resistor 10B, the third resistor 10C, and the fourth resistor 10D shown in FIG. 16 are resistors having fixed resistance values. The first voltage signal merging wire 13 and the second voltage signal merging wire 14 shown in FIG. 9 are not provided. The first voltage signal wire 9A, the second voltage signal wire 9B, the third voltage signal wire 9C, and the fourth voltage signal wire 9D are coupled to the current calculator 20.

The first resistor 10A, the second resistor 10B, the third resistor 10C, and the fourth resistor 10D are attached to the first voltage signal wire 9A, the second voltage signal wire 9B, the third voltage signal wire 9C, and the fourth voltage signal wire 9D, respectively. The current calculator 20 is coupled to the voltage detection contacts 8A to 8D via the voltage signal wires 9A to 9D and the resistors 10A to 10D. In one embodiment, an amplifier for amplifying the voltage signal may be provided between the resistors 10A to 10D and the current calculator 20.

The current calculator 20 converts the detected voltages of analog signals calculated from the voltage signals transmitted through the voltage signal wires 9A to 9D into digital signals, reads them, and performs the correction process on the detected voltages of the digital signals, thereby performing the same operation as changing the resistance values of the resistors 10A to 10D and adjusting the composite detection voltage in the previously described embodiment.

More specifically, the current calculator 20 multiplies a negative-side correction coefficient by a negative-characteristic-side detected voltage (i.e., a detected voltage at the negative characteristic position) between the first voltage detection contact 8A and the second voltage detection contact 8B calculated from the voltage signals to calculate a corrected negative-characteristic-side detected voltage. Similarly, the current calculator 20 multiplies a positive-side correction coefficient by a positive-characteristic-side detected voltage (i.e., a detected voltage at the positive characteristic position) between the third voltage detection contact 8C and the fourth voltage detection contact 8D calculated from the voltage signals to calculate a corrected positive-characteristic-side detected voltage. The negative-characteristic-side detected voltage between the first voltage detection contact 8A and the second voltage detection contact 8B is determined from the voltage signals transmitted through the first voltage signal wire 9A and the second voltage signal wire 9B, and the positive-characteristic-side detected voltage between the third voltage detection contact 8C and the fourth voltage detection contact 8D is determined from the voltage signals transmitted through the third voltage signal wire 9C and the fourth voltage signal wire 9D.

The positive-side correction coefficient and the negative-side correction coefficient are calculated by a simulation or the like to bring the temperature coefficient of resistance of the shunt resistor 1 calculated from the composite detection voltage close to 0. This composite detection voltage is calculated by combining the corrected negative-characteristic-side detected voltage and the corrected positive-characteristic-side detected voltage. The current calculator 20 determines the current flowing through the shunt resistor 1 based on the composite detection voltage calculated by combining the corrected negative-characteristic-side detected voltage and the corrected positive-characteristic-side detected voltage, and the known resistance value of the shunt resistor 1.

Such internal processing of the current calculator 20 can provide the same result as the adjustment of the resistors 10A to 10D described with reference to FIGS. 12 to 15. When the negative-characteristic-side detected voltage (the detected voltage at the negative characteristic position) between the first voltage detection contact 8A and the second voltage detection contact 8B calculated from the voltage signals is multiplied by the negative-side correction coefficient, a ratio of the negative-characteristic-side detected voltage to the positive-characteristic-side detected voltage in the composite detection voltage changes. Similarly, when the positive-characteristic-side detected voltage (the detected voltage at the positive characteristic position) between the third voltage detection contact 8C and the fourth voltage detection contact 8D calculated from the voltage signals is multiplied by the positive-side correction coefficient, a ratio of the positive-characteristic-side detected voltage to the negative-characteristic-side detected voltage in the composite detection voltage changes.

The temperature coefficient of resistance TCR3 is calculated from the composite detection voltage that is determined from the combination of the corrected negative-characteristic-side detected voltage and the corrected positive-characteristic-side detected voltage. The current calculator 20 calculates the composite detection voltage by combining the corrected negative-characteristic-side detected voltage and the corrected positive-characteristic-side detected voltage, and calculates the current flowing through the shunt resistor 1 from the composite detection voltage and the known resistance value of the shunt resistor 1. According to this embodiment, as shown in FIG. 17, the temperature coefficient of resistance TCR3 of the shunt resistor 1 approaches 0, so that the current calculator 20 can accurately determine the current without being affected by the temperature of the shunt resistor 1.

The negative-side correction coefficient and the positive-side correction coefficient may be determined in advance by a simulation or the like, or may be determined by an inspection after the current detection apparatus is manufactured (before shipment). Specifically, a predetermined current is passed through the shunt resistor 1, and the composite detection voltage is measured by the current calculator 20 while changing the temperature of the shunt resistor 1, and the negative-side correction coefficient and the positive-side correction coefficient are determined such that the change in the composite detection voltage becomes small (i.e., the temperature coefficient of resistance TCR3 approaches 0).

In one embodiment, either the negative-characteristic-side detected voltage or the positive-characteristic-side detected voltage may be multiplied by one of the negative-side correction coefficient and the positive-side correction coefficient to calculate the corrected negative-characteristic-side detected voltage or the corrected positive-characteristic-side detected voltage. Even in this case, the correction coefficient multiplied by the negative-characteristic-side detected voltage or the positive-characteristic-side detected voltage is a coefficient that can bring the temperature coefficient of resistance TCR3 close to 0. Specifically, while a predetermined current is passed through the shunt resistor 1 and the temperature of the shunt resistor 1 is changed, the composite detection voltage is measured by the current calculator 20, and a correction coefficient that reduces the change in the composite detection voltage (i.e., brings the temperature coefficient of resistance TCR3 close to 0) is determined.

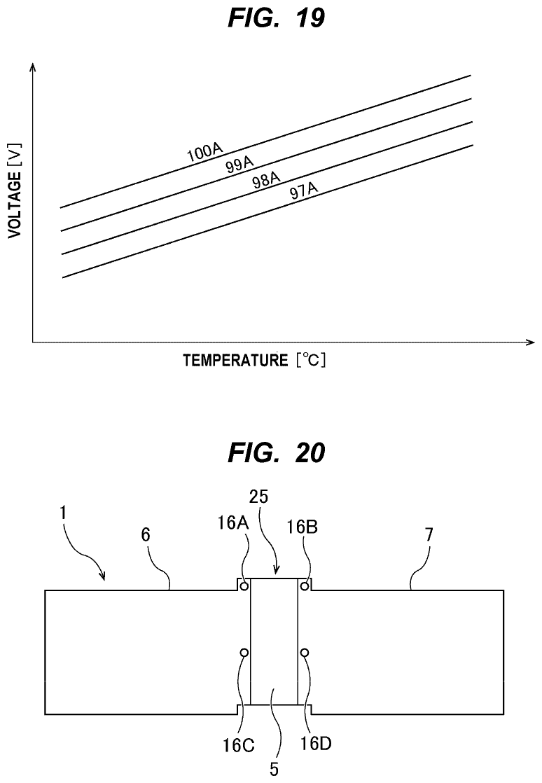

Next, still another embodiment of the current measuring apparatus will be described with reference to FIGS. 18 and 19. Configuration and operation of this embodiment that are not specifically described are the same as those of the embodiments described with reference to FIGS. 16 and 17, and therefore duplicated descriptions will be omitted.

In this embodiment, the current flowing through the shunt resistor 1 is directly calculated using a current calculation formula. Specifically, the current calculator 20 has the current calculation formula configured to calculate the current flowing through the shunt resistor 1 from the negative-characteristic-side detected voltage (the detected voltage at the negative characteristic position) between the first voltage detection contact 8A and the second voltage detection contact 8B calculated from the voltage signals and the positive-characteristic-side detected voltage (the detected voltage at the positive characteristic position) between the third voltage detection contact 8C and the fourth voltage detection contact 8D calculated from the voltage signals. The current calculation formula is a function formula derived from a first function and a second function. The first function indicates a relationship between the negative-characteristic-side detected voltage between the first voltage detection contact 8A and the second voltage detection contact 8B and the temperature of the shunt resistor 1, and the second function indicates a relationship between the positive-characteristic-side detected voltage between the third voltage detection contact 8C and the fourth voltage detection contact 8D and the temperature of the shunt resistor 1.

FIG. 18 is a graph showing the relationship between the negative-characteristic-side detected voltage between the first voltage detection contact 8A and the second voltage detection contact 8B and the temperature of the shunt resistor 1. While currents of 100 amperes, 99 amperes, 98 amperes, and 97 amperes are passed through the shunt resistor 1, the temperature of the shunt resistor 1 and the negative-characteristic-side detected voltage between the first voltage detection contact 8A and the second voltage detection contact 8B were measured. Linear approximation graphs shown in FIG. 18 were created from the obtained temperature measurement data and voltage measurement data. Each graph shown in FIG. 18 is expressed by the following first function:

$$Y 1 = a * 1 * t + b * 1 \qquad ( 1 )$$

where, Y1 represents the negative-characteristic-side detected voltage [V] between the first voltage detection contact 8A and the second voltage detection contact 8B, a represents a coefficient (constant), t represents the temperature [° C.] of the shunt resistor 1, b represents a coefficient (constant), and I represents the current [A] passed through the shunt resistor 1. The coefficients a and b can be calculated from the temperature measurement data and the voltage measurement data.

FIG. 19 is a graph showing the relationship between the positive-characteristic-side detected voltage between the third voltage detection contact 8C and the fourth voltage detection contact 8D and the temperature of the shunt resistor 1. While currents of 100 amperes, 99 amperes, 98 amperes, and 97 amperes are passed through the shunt resistor 1, the temperature of the shunt resistor 1 and the positive-characteristic-side detected voltage between the third voltage detection contact 8C and the fourth voltage detection contact 8D were measured. Linear approximation graphs shown in FIG. 19 were created from the obtained temperature measurement data and voltage measurement data. Each graph shown in FIG. 19 is expressed by the following second function,

$$Y 2 = c * 1 * t + d * 1 \qquad ( 2 )$$

where, Y2 represents the positive-characteristic-side detected voltage [V] between the third voltage detection contact 8C and the fourth voltage detection contact 8D, c represents a coefficient (constant), t represents the temperature [° C.] of the shunt resistor 1, d represents a coefficient (constant), and I represents the current [A] passed through the shunt resistor 1. The coefficients c and d can be calculated from the temperature measurement data and the voltage measurement data.

A current calculation formula and a temperature calculation formula can be derived from the first function (1) and the second function (2) as follows.

Current calculation formula

$$1 = ( ( Y 1 \times c ) - ( Y 2 \times a ) ) / ( ( b \times c ) - ( a \times d ) ) \qquad ( 3 )$$

Temperature calculation formula

$$t = ( ( Y 2 \times b ) - ( Y 1 \times d ) ) / ( ( Y 1 \times c ) - ( Y 2 \times a ) ) \qquad ( 4 )$$

In the above current and temperature calculation formulas, specific values of a, b, c, and d are already determined. Therefore, once the negative-characteristic-side detected voltage Y1 and the positive-characteristic-side detected voltage Y2 are obtained, the current [A] flowing through shunt resistor 1 and the temperature [° C.] of the shunt resistor 1 can be calculated from the current calculation formula and the temperature calculation formula.

The current calculator 20 has the current calculation formula and the temperature calculation formula stored in advance in its memory 20a. The current calculator 20 calculates the negative-characteristic-side detected voltage Y1 (the detected voltage at the negative characteristic position) between the first voltage detection contact 8A and the second voltage detection contact 8B from the voltage signals acquired through the first voltage signal wire 9A and the second voltage signal wire 9B, and calculates the positive-characteristic-side detected voltage Y2 (the detected voltage at the positive characteristic position) between the third voltage detection contact 8C and the fourth voltage detection contact 8D from the voltage signals acquired through the third voltage signal wire 9C and the fourth voltage signal wire 9D. The current calculator 20 can then calculate the current [A] flowing through the shunt resistor 1 by inputting the negative-characteristic-side detected voltage Y1 and the positive-characteristic-side detected voltage Y2 into the current calculation formula. According to this embodiment, the current flowing through the shunt resistor can be directly calculated using the current calculation formula without correcting and combining the negative-characteristic-side detected voltage and the positive-characteristic-side detected voltage. Furthermore, the current calculator 20 can calculate the temperature [° C.] of the shunt resistor 1 by inputting the negative-characteristic-side detected voltage Y1 and the positive-characteristic-side detected voltage Y2 into the temperature calculation formula.

In the above description, the current calculation formula and the temperature calculation formula are obtained from the relationship between the negative-characteristic-side detected voltage Y1 and the positive-characteristic-side detected voltage Y2 and the temperature. In one embodiment, if there is a difference between the first function and the second function, similar current calculation formulas and temperature calculation formulas can be obtained. In that case, a negative-characteristic-side detected voltage Y1 and a negative-characteristic-side detected voltage Y2 may be used, or a positive-characteristic-side detected voltage Y1 and a positive-characteristic-side detected voltage Y2 may be used. Specifically, the current calculation formula and the temperature calculation formula are derived from a relationship between the first characteristic-side detected voltage Y1 and the second characteristic-side detected voltage Y2 and the temperature. The current calculator 20 can calculate the current [A] flowing through the shunt resistor 1 by inputting the first characteristic-side detected voltage Y1 and the second characteristic-side detected voltage Y2 into the current calculation formula. Furthermore, the current calculator 20 can calculate the temperature [° C.] of the shunt resistor 1 by inputting the first characteristic-side detected voltage Y1 and the second characteristic-side detected voltage Y2 into the temperature calculation formula.

The graphs in FIGS. 18 and 19 are created using linear approximation. When the graph shows curve data that is significantly curved, it is a complicated operation to express the graph in mathematical formula. Therefore, instead of the current calculation formula and the temperature calculation formula, a data table can be stored in the memory 20a. The current calculator 20 can derive the current [A] flowing through the shunt resistor 1 and the temperature [° C.] of the shunt resistor 1 from the data table by referring to the negative-characteristic-side detected voltage Y1 and the positive-characteristic-side detected voltage Y2.

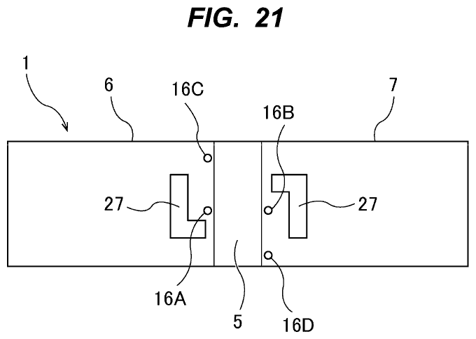

The shunt resistor 1 in each embodiment described so far has the slits 11, 12 shown in FIG. 1 and FIG. 2, but other types of shunt resistors can also be used. For example, as shown in FIG. 20, a shunt resistor 1 may have a protruding portion 25 protruding in its width direction. In this example, a part of the resistance element 5 and a part of the pair of electrodes 6, 7 form the protruding portion 25. The protruding portion 25 has a rectangular shape when viewed from above. Furthermore, as shown in FIG. 21, a shunt resistor 1 may have L-shaped holes 27 in the electrodes 6, 7, respectively. The shape of the holes 27 is not limited to the shape shown in FIG. 21, and may be another shape.

The previous description of embodiments is provided to enable a person skilled in the art to make and use the present invention. Moreover, various modifications to these embodiments will be readily apparent to those skilled in the art, and the generic principles and specific examples defined herein may be applied to other embodiments. Therefore, the present invention is not intended to be limited to the embodiments described herein but is to be accorded the widest scope as defined by limitation of the claims.

### Industrial Applicability

The present invention is applicable to a shunt resistor and a current detection apparatus.

### Reference Signs List

1 shunt resistor
2 current detector
3 base plate
5 resistance element
6,7 electrode
8A to 8D voltage detection contact
9A to 9D voltage signal wire
1,12 slit
13,14 voltage signal merging wire 1
16A to 16D voltage detection terminal
19 condenser
20 current calculator
25 protrusion
27 hole

1. A shunt resistor comprising:
a resistance element;
a first electrode and a second electrode coupled to both sides of the resistance element;
a first voltage detection terminal and a second voltage detection terminal provided at first characteristic positions of the first electrode and the second electrode where a temperature coefficient of resistance of the shunt resistor is a first coefficient; and
a third voltage detection terminal and a fourth voltage detection terminal provided at second characteristic positions of the first electrode and the second electrode where the temperature coefficient of resistance of the shunt resistor is a second coefficient, the first coefficient and the second coefficient having different numerical values.

2. The shunt resistor according to claim 1, wherein the first coefficient has a negative numerical value, and the second coefficient has a positive numerical value.

3. The shunt resistor according to claim 1, wherein either the first voltage detection terminal and the third voltage detection terminal provided on the first electrode, or the second voltage detection terminal and the fourth voltage detection terminal provided on the second electrode comprise a common voltage detection terminal.

4. A current detection apparatus comprising:
a shunt resistor having a resistance element, a first electrode, and a second electrode, the first electrode and the second electrode being coupled to both sides of the resistor; and
a current detector electrically coupled to the shunt resistor, the current detector including:
a first voltage detection contact and a second voltage detection contact electrically coupled to negative characteristic positions of the first electrode and the second electrode where a temperature coefficient of resistance of the shunt resistor has a negative value;
a third voltage detection contact and a fourth voltage detection contact electrically coupled to positive characteristic positions of the first electrode and the second electrode where a temperature coefficient of resistance of the shunt resistor has a positive value;
a first voltage signal wire, a second voltage signal wire, a third voltage signal wire, and a fourth voltage signal wire coupled to the first voltage detection contact, the second voltage detection contact, the third voltage detection contact, and the fourth voltage detection contact, respectively;
a resistor coupled to at least one of the first voltage signal wire, the second voltage signal wire, the third voltage signal wire, and the fourth voltage signal wire;
a first voltage signal merging wire configured to merge voltage signals from the first voltage signal wire and the third voltage signal wire; and
a second voltage signal merging wire configured to merge voltage signals from the second voltage signal wire and the fourth voltage signal wire,
wherein the resistor has a resistance value that brings a temperature coefficient of resistance of the shunt resistor, calculated from voltage signals from the first voltage signal merging wire and the second voltage signal merging wire, close to zero.

5. A current detection apparatus comprising:
a shunt resistor having a resistance element, a first electrode, and a second electrode, the first electrode and the second electrode being coupled to both sides of the resistor; and
a current detector electrically coupled to the shunt resistor, the current detector including:
a first voltage detection contact and a second voltage detection contact electrically coupled to negative characteristic positions of the first electrode and the second electrode where a temperature coefficient of resistance of the shunt resistor has a negative value;
a third voltage detection contact and a fourth voltage detection contact electrically coupled to positive characteristic positions of the first electrode and the second electrode where a temperature coefficient of resistance of the shunt resistor has a positive value; and
a current calculator into which voltage signals from the first voltage detection contact, the second voltage detection contact, the third voltage detection contact, and the fourth voltage detection contact are input,
wherein the current detector is configured to:
correct at least one of a negative-characteristic-side detected voltage between the first voltage detection contact and the second voltage detection contact and a positive-characteristic-side detected voltage between the third voltage detection contact and the fourth voltage detection contact by multiplying a correction coefficient by at least one of the negative-characteristic-side detected voltage and the positive-characteristic-side detected voltage which are calculated from the voltage signals; and
determine a current flowing through the shunt resistor based on a composite detection voltage calculated from a known resistance value of the shunt resistor and the negative-characteristic-side detected voltage and the positive-characteristic-side detected voltage, at least one of which has been corrected, and
the correction coefficient has a numerical value that brings a temperature coefficient of resistance of the shunt resistor, calculated from the composite detection voltage, close to zero.

6. A current detection apparatus comprising:
a shunt resistor having a resistance element, a first electrode, and a second electrode, the first electrode and the second electrode being coupled to both sides of the resistor; and
a current detector electrically coupled to the shunt resistor, the current detector including:
a first voltage detection contact and a second voltage detection contact electrically coupled to first characteristic positions of the first electrode and the second electrode where a temperature coefficient of resistance of the shunt resistor has a first value;
a third voltage detection contact and a fourth voltage detection contact electrically coupled to second characteristic positions of the first electrode and the second electrode where a temperature coefficient of resistance of the shunt resistor has a second value; and
a current calculator into which voltage signals from the first voltage detection contact, the second voltage detection contact, the third voltage detection contact, and the fourth voltage detection contact are input,
wherein the current calculator is configured to derive a value of a current flowing through the shunt resistor from a first characteristic-side detected voltage between the first voltage detection contact and the second voltage detection contact and a second characteristic-side detected voltage between the third voltage detection contact and the fourth voltage detection contact, the first characteristic-side detected voltage and the second characteristic-side detected voltage being calculated from the voltage signals.

7. The current detection apparatus according to claim 6, wherein the current calculator has a current calculation formula configured to calculate the value of the current flowing through the shunt resistor from the first characteristic-side detected voltage and the second characteristic-side detected voltage.

8. The current detection apparatus according to claim 6, wherein the current calculator has a data table showing a relationship between the first and second characteristic-side detected voltages and a value of a current flowing through the shunt resistor.

9. The current detection apparatus according to claim 6, wherein the current calculator has a function of deriving a temperature of the shunt resistor from the first characteristic-side detected voltage and the second characteristic-side detected voltage.
